(19) United States
(12) Patent Application Publication
(10) Pub. No.: US 2010/0207600 A1
(43) Pub. Date: Aug. 19, 2010

(54) Variable-Electric-Power Self-Regulating Cable Exhibiting PTC Behaviour, Connector Therefor, a Device Comprising Them, and Use of Said Device

(75) Inventors: Philippe Paul Bert, Romagny (FR); Christian Lagreve, La Chepelle Biche (FR); Frederic Plet, Romagny (FR)

Correspondence Address: MCANDREWS HELD & MALLOY, LTD, 500 WEST MADISON STREET, SUITE 3400, CHICAGO, IL, 60661, US

(73) Assignee: Acome Societe Cooperative de Production, Societe Anonyme, a Capital Variable, Paris (FR)

(21) Appl. No.: 12/678,246

(22) PCT Filed: Sep. 10, 2008
(86) PCT No.: PCT/FR2008/051614

§ 371 Date: Mar. 15, 2010

(30) Foreign Application Priority Data
Sep. 18, 2007 (FR) 0706541

(51) Int. Cl. H03H 2/00; H01B 7/00; H02G 3/00

(52) U.S. Cl. 323/369; 174/113 R; 174/115; 174/70 R

(57) ABSTRACT

The present invention relates to a variable-electric-power self-regulating cable exhibiting PTC behaviour, to a specific connector therefor, to a device comprising said cable and said connector, and to the use of said device to generate variable electric power using a single cable.

This invention relates to a variable electric power self-regulating cable exhibiting PTC behavior, to a specific connector therefore, to a device comprising said cable and said connector, and to the use of said device to generate variable electric power using a single cable.

Cables exhibiting PTC (Positive Temperature Coefficient) behavior exist within the framework of freeze protection and temperature maintenance-related applications, i.e., cables for which it is possible to observe an increase in the electrical resistance thereof along with temperature, until they deliver a very low or even zero-intensity current. As a matter of fact, when these cables are subjected to any electrical voltage, the electrical current will heat the material via the Joule effect, the amount of heat energy released by the Joule effect will induce mobility in the macromolecular chains, a distancing of the conductive particles from one another and an expansion of the material. This increase in the internal temperature of the cable will thus increase the resistance of the cable, the end result of which will be to decrease the electrical power of the cable. Consequently, this progressive decrease in the electrical power will continue until reaching zero power, and thus a top self-heating temperature of the material. The cable is thus capable of self-regulating in terms of electrical resistance and therefore electrical power and consequently temperature.

One of the special features of these cables is that they can be self-regulating due to the nature of the composition materials thereof. This has also been described by the filing company in applications EP 0965138 B1 and FR 0705142. Generally speaking, the self-regulation of the cable is due to the fact that, by modifying the internal temperature of the cable, the electrical power generated by same will likewise be modified.

That having been said, it is impossible today to find a PTC-behavior cable on the market which is capable of generating various power levels at a given temperature, as well as a connector specifically suited to these types of cables.

Cables exist, however, e.g., the VLBTV by the RAYCHEM Corporation, which possess a number of electrical conductors greater than two, but the function of these conductors is to increase the total cross-sectional area of these conductors for heating applications or temperature maintenance over long distances, and to do so at 480 and 600 V.

Therefore, an actual need exists for a cable exhibiting PTC behavior which enables various electrical power levels to be generated at a given temperature.

After considerable research, the Applicant has found a variable electric power self-regulating cable exhibiting PTC (Positive Temperature Coefficient) behavior which completely satisfies these criteria. The cable according to the invention is characterized in that it includes at least three electrical conductors separated by a polymer alloy referred to as having PTC behavior, all of the electric conductors being intended to be connected in pairs. The term “connected in pairs” is understood to mean either one conductor connected to another conductor or else at least two conductors short-circuited between each other, the end result being connected to another connector.

The cable according to the invention contains at least three electrical conductors encased in a polymer-based semiconductor alloy filled with electrically conductive particles. This polymer-based alloy exhibits PCT behavior, i.e., an increase in the electrical resistance thereof along with temperature until delivering a very low or zero-intensity current. This polymer alloy can be as described in patent EP 0965138 or in application FR 0705142. More particularly, it includes a polar polyolefin, a conductive filler and a matrix polymer. The polar polyolefin, possibly filled completely or partially with carbon black, is chosen from the group comprising vinyl ethylene/acetate polymers, C₁-C₆ alkyl ethylene/acrylate copolymers, or the mixtures thereof. As concerns the matrix polymer, it can be chosen from among the poly (C₁-C₄ alkylene) terephthalates, polyamides, polypropylenes, polycarbonates, polyester and polyether copolymers, poly(methyl methacrylates) or the mixtures thereof. The nature of the polymer is defined by the conditions of use of the alloy, the aptitude thereof to exhibit PCT behavior within the desired temperature range as well as with respect to the mechanical characteristics capable of giving same a particular geometry and the specific flexible-type deformations.

According to a preferred embodiment, the variable electric power self-regulating cable according to the invention is characterized in that the quantity of polymer alloy separating the two connected conductors determines the resistance of the cable.

Therefore, by the selection of the conductors connected in pairs, this invention enables the obtainment of various electrical resistance (ohmic) values and, consequently, electrical power values for the cable. As a matter of fact, since the resistance is based on the quantity of polymer material separating two connected conductors, in order to vary this resistance, it suffices to connect conductors which are relatively distant from one another. When connecting the cable, it is possible to select the conductors providing the degree of electrical resistance suited to the desired application: the same cable can thus provide a combination of electrical resistances, and therefore various electrical power levels for a single temperature, and each power level will have its own variation in relation to temperature.

The cable according to the invention can be manufactured by the process described in patent EP 0965138 or in that of application FR 0705142. In particular, said process is characterized in that it includes the following steps, in which:
the various compatible components of a polymer alloy are mixed, comprising a polar olefin, a matrix polymer, a conductive filler such as carbon black and possibly non-conductive fillers,
the resulting mixture is extruded so as to obtain granulates,
the granulates are extruded around electrically conductive strands (i.e., conductors),
the ribbon thus formed is then covered with an electrically insulating material,
the assembly is inserted into a protective metallic sleeve, and finally,
the sleeve is enclosed in an insulating sheath.

According to a preferred embodiment, the variable electric power self-regulating cable according to the invention is characterized in that said electrical conductors are all identical.

According to a preferred embodiment, the variable electric power self-regulating cable according to the invention is characterized in that at least one of said electrical conductors is of a different cross-sectional area. In this case, the variation can likewise be made by connecting to a conductor having a different cross-sectional area.

The electrical conductors are made of a material chosen from the group comprising, in particular, copper, nickel-plated copper, tinned copper, aluminum and the mixtures thereof. Generally speaking, all of the conductors are made of identically the same material. However, according to a preferred embodiment, in order to increase the possible applications of the cable according to the invention, this variable electric power self-regulating cable is characterized in that at least one of said electrical conductors is manufactured from different materials.

According to a preferred embodiment, the variable electric power self-regulating cable according to the invention is characterized in that the distance between two successive electrical conductors is identical.

According to a preferred embodiment, the variable electric power self-regulating cable according to the invention is characterized in that the distance between two successive electrical conductors is different.

The cable according to the invention comprises the following advantages:
it considerably reduces the number of cable references by using a single cable enabling several electrical power levels to be generated,
it can be used as a multi-use supply voltage cable,
it is easy to adapt the production machinery to obtain four, six or eight electrical conductors in one and the same cable, and
it allows a component such as a thermostat to be eliminated.

This invention likewise relates to a connector intended for a variable electric power self-regulating cable exhibiting PTC behavior according to the invention, characterized in that it includes a means enabling connection to the electrical power supply and a means enabling the electrical conductors to be connected in pairs.

According to a preferred embodiment, the connector according to the invention is characterized in that the means of connection is a rotary knob, the rotation thereof thereby making it possible to preselect the contacting of the cable conductors with the electrical power supply.

According to a preferred embodiment, the connector according to the invention is characterized in that the means of connection is translational, the translation of the electrical contacts thereby making it possible to preselect the contacting of the cable conductors with the electrical power supply.

According to a preferred embodiment, the connector according to the invention is characterized in that the means of connection is a plug-in, the plug thereby making it possible to preselect the contacting of the cable conductors with the electrical power supply by connecting said conductors to be connected in the housing in order to select the resistance value. Other means of connection are foreseeable such as push-buttons, electronic switches and relays.

This invention likewise relates to a device variable electric power to be generated, characterized in that it includes at least one cable according to the invention and at least one connector according to the invention.

This invention further relates to the use of the device according to the invention for generating variable electric power using a single cable comprising at least three electrical conductors inserted into an alloy referred to as having PTC behavior, this alloy itself consisting of polymers filled with electrically conductive particles.

In this way, by using one and the same cable, the user can choose the desired power level. To do so, they connect together the two connectors which will enable them to obtain said power level. If, during use or for another application, they wish to obtain another power level, they will then connect together other connectors. In this way, there is no further need to change cables.

Other aspects, objects, advantages and characteristics of the invention will be introduced upon reading the following non-restrictive description which describes preferred embodiments of the invention, and which is given for exemplary purposes only, with reference to the following figures, in which:

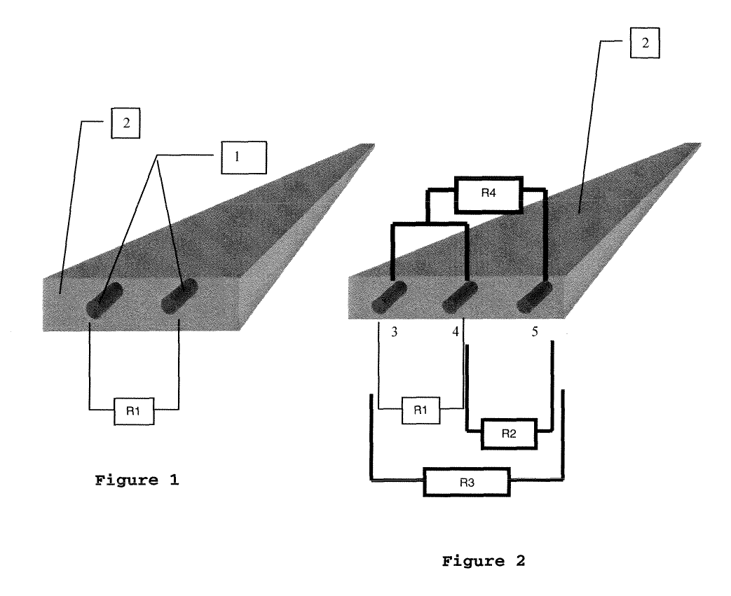

FIG. 1 shows a conventional PTC behavior cable,

FIG. 2 shows a PTC behavior cable according to the invention,

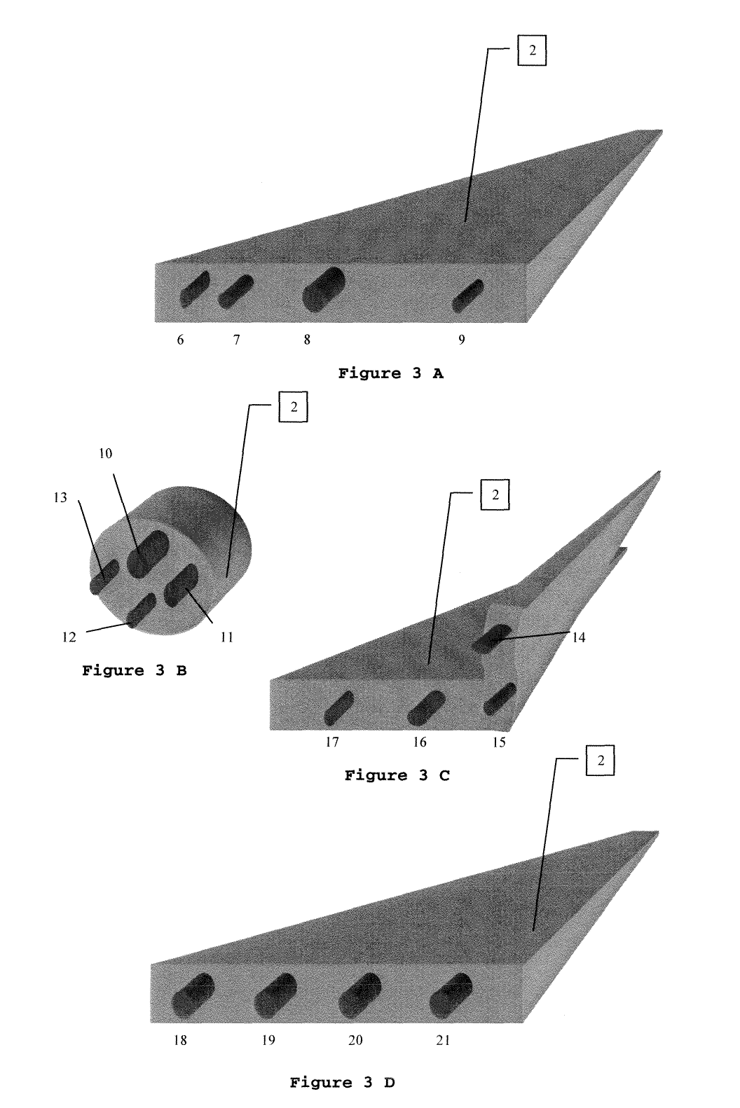

FIG. 3 shows various alternatives of the cable according to the invention,

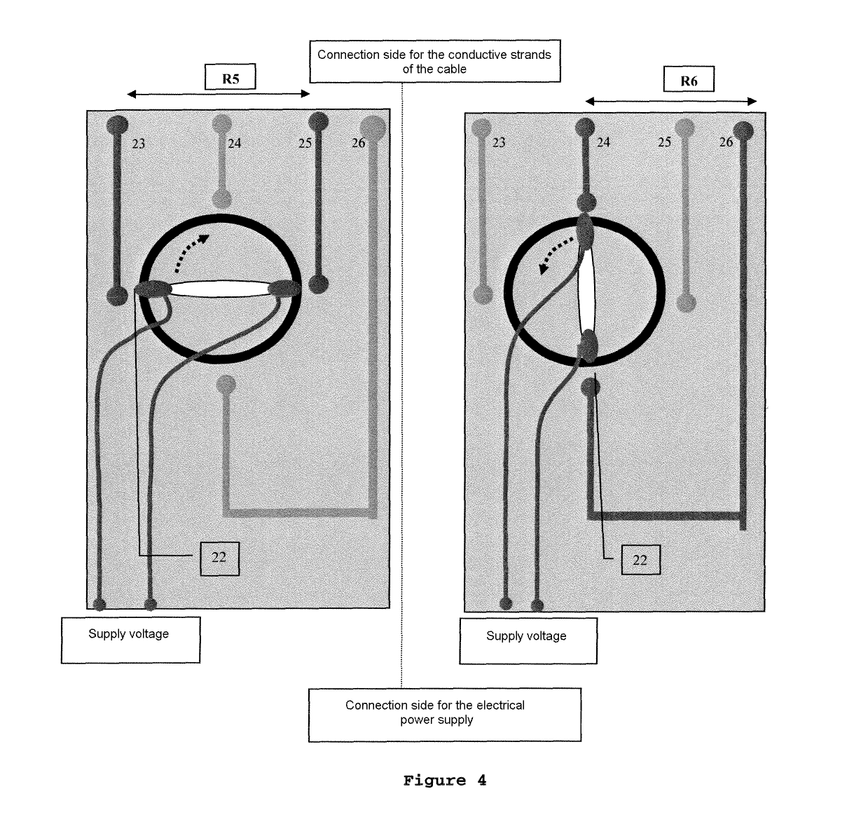

FIG. 4 is a schematic representation of rotary knob connection means,

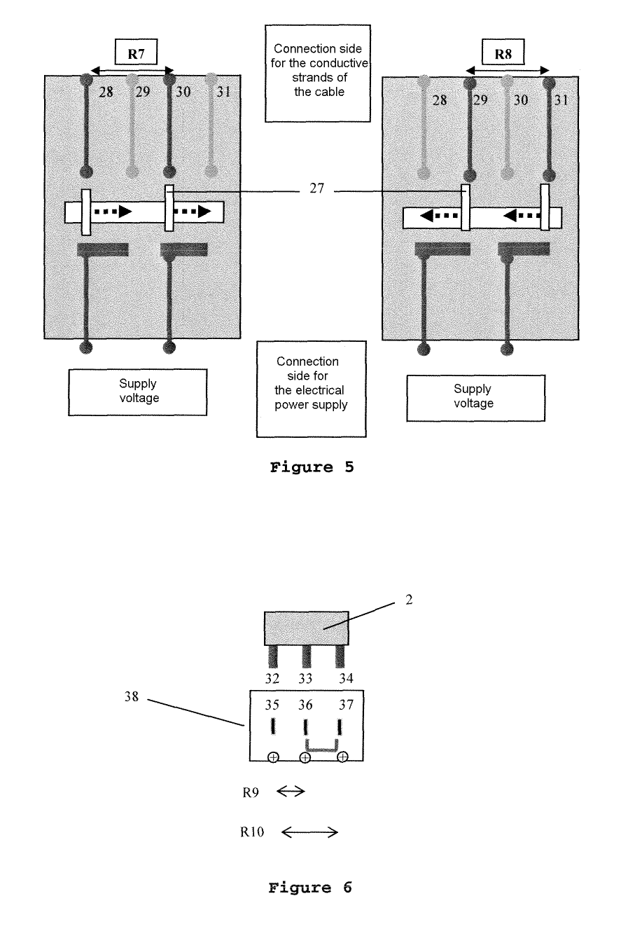

FIG. 5 is a schematic representation of a translation connection means,

FIG. 6 is a schematic representation of a plug-in connection means,

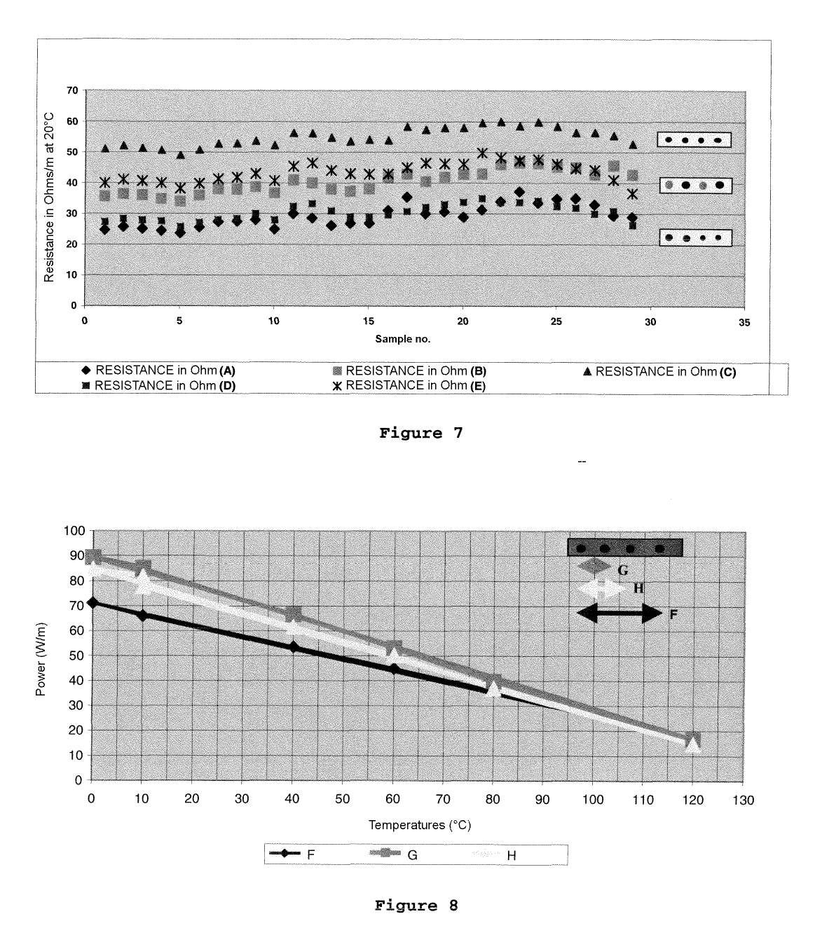

FIG. 7 is a graphic representation of the various electrical resistances obtainable with relation to connection of the electrical conductors on a four-conductor sample, and

FIG. 8 is a graphic representation of the potential for obtaining an increasing power level according to the choice of conductors.

A conventional self-regulating cable exhibiting PTC behavior is shown in FIG. 1, which consists of electrical conductors (1) encased in a polymer alloy referred to as having PTC behavior (2). The quantity of polymer alloy separating the two conductors determines the resistance and is shown by R1.

A cable according to the invention is shown in FIG. 2, and consists of electrical conductors (3), (4) and (5) encased in a polymer alloy referred to as exhibiting PTC behavior (2). The quantity of polymer alloy separating the various conductors determines the resistance: the resistance between the conductors (3), (4) is shown by R1; the resistance between conductors (4) and (5) is shown by R2, the resistance between conductors (3) and (5) is shown by R3 and the resistance between the result of the short circuit of conductors (3) and (4), on the one hand, and the conductor (5), on the other hand, is shown by R4. In this way, the resistance is modified according to the choice of conductors connected together.

Various alternatives of the cable according to the invention are shown in FIGS. 3A, 3B, 3C and 3D. A cable is shown in FIG. 3A which has four electrical conductors of different cross-sectional areas (6 to 9) distributed differently inside the cable, thereby creating multiple resistance possibilities. A cable is shown in FIGS. 3B and 3C which has four electrical conductors of different cross-sectional areas (10 to 17) distributed differently inside cables of various geometries, thereby creating various resistance possibilities. A cable is shown in FIG. 3D which has four electrical conductors of identical cross-sectional areas (18 to 21) which are distributed identically in the cable, thereby creating various resistance possibilities. It is thus possible to obtain various resistances and therefore various power levels in relation to temperature by varying the cross-sectional area of the electrical conductors and the distribution thereof inside the cable itself, and by the selection of the connectors connected together, while at the same time having the possibility of creating cables of different geometries.

A rotary knob connection means is shown in FIG. 4, which enables the resistance R5 or R6 of the PCT behavior cable according to the invention to be selected. To select resistance R5, it suffices to rotate the rotary knob such that the electrical contacts (22) of the rotary knob can come into contact with the electrical conductors (23) and (25). Similarly, in order to select resistance R6, it suffices to rotate the rotary knob such that electrical contacts (22) of the rotary knob can come into contact with the electrical contacts (24) and (26).

A translational connection means is shown in FIG. 5, which enables the resistance R7 or R8 of the PTC behavior cable according to the invention to be selected. To select resistance R7, it suffices to move the electrical contacts (27) such that they can come into contact with the conductors (28) and (30). Similarly, in order to select resistance R8, it suffices to move the electrical contacts (27) such that they can come into contact with the electrical conductors (29) and (31).

A plug-in connection means is shown in FIG. 6, which enables the resistance R9 or R10 of the PTC behavior cable according to the invention to be selected. To select resistance R9, it suffices to insert the electrical conductors (32) and (33) of the cable into the corresponding plug receptacles (35) and (36) of the connector housing (38). Similarly, in order to select resistance R10, it suffices to insert the electrical contacts (32) and (34) of the cable into the corresponding plug receptacles (35) and (37) of the connector housing (38).

### EXAMPLES

### Example 1

### Resistance in Relation to the Connections

A four-conductor self-regulating cable is prepared, as shown in FIG. 3D of this application, the preparation of said cable having been carried out according to example 1 of patent application FR 0705142.

The following various connections are made between the conductors: A: 20 and 21, B: 18 and 20, C: 18 and 21, D: 18 and 19, E: 19 and 21. The name of the curve corresponds to that of the connections.

For each connection, the resistance measurements are carried out every meter over a total length of 30 meters. The results are presented by the curves of FIG. 7. The latter shows the various electrical resistances obtainable in relation to the connection of the electrical conductors on a four-conductor cable.

FIG. 7 shows the perfect symmetry of the PTC behavior heating element with the isotropy of the electrical properties of the cable, the homogeneity of the distribution of the PCT behavior conductive fillers of the alloy. This makes it possible to have several identical and non-identical resistances on a single product.

This connection combination offers the possibility of having several cable power levels, and that also enables the resistance of a cable to be multiplied.

Multiplication of the resistance offers the possibility of increasing the production volume of a cable with a single resistance: as a matter of fact, with a four-conductor cable, we have the possibility of cutting the cable in two and of having two cables with the same resistance.

Based on the choice of conductors, it is possible to obtain identical or non-identical resistances (symmetry of the cable properties, several combinations).

### Example 2

### Power Curve

A cable identical to the one implemented in example 1 was used. The following connections were made in succession: F: 18 and 21, G: 18 and 19 and H: 18 and 20. The electrical power level in relation to temperature was measured for each connection, and the results are shown in FIG. 8. The name of the curve corresponds to that of the connections.

FIG. 8 shows that, based on the choice of connectors, it is possible to have several power levels. The power level can thus be regulated based on the choice of connections.

Although this invention has been described hereinabove by way of examples of the preferred embodiments thereof, it is understood that it can be modified without departing from the spirit and nature of the invention as defined in the appended claims.

1. Variable electric power self-regulating cable exhibiting PTC (Positive Temperature Coefficient) behavior, wherein said cable comprises at least three electrical conductors separated by a polymer alloy referred to as having PTC behavior, all of the electric conductors being intended to be connected in pairs.

2. Variable electric power self-regulating cable of claim 1, wherein the quantity of polymer alloy separating the two connected conductors determines the resistance of the cable.

3. Variable electric power self-regulating cable as claimed in claim 1, wherein said electrical conductors are all identical.

4. Variable electric power self-regulating cable as claimed in claim 1, wherein at least one of said electrical conductors is of a different cross-sectional area.

5. Variable electric power self-regulating cable as claimed in claim 1, wherein at least one of said electrical conductors is manufactured from different materials.

6. Variable electric power self-regulating cable as claimed in claim 1, wherein the distance between two successive electrical conductors is identical.

7. Variable electric power self-regulating cable as claimed in claim 1, wherein the distance between two successive electrical conductors is different.

8. Connector intended for a variable electric power self-regulating cable exhibiting PTC behavior as claimed in claim 1, wherein said connector comprises a means enabling same to be connected to the electrical power supply and a means enabling the electrical conductors to be connected in pairs.

9. Connector of claim 8, wherein the means of connection is a rotary knob, the rotation thereof thereby making it possible to preselect the contacting of the cable conductors with the electrical power supply.

10. Connector of claim 8, wherein the means of connection is translational, the translation of the electrical contacts thereby making it possible to preselect the contacting of the cable conductors with the electrical power supply.

11. Connector of claim 8, wherein the means of connection is a plug-in, the plug thereby making it possible to preselect the contacting of the cable conductors with the electrical power supply by connecting said conductors to be connected in the housing in order to select the resistance value.

12. Device enabling variable electric power to be generated, wherein said device comprises at least one cable as claimed in claim 1 and at least one connector as claimed in claim 8.

13. A method for generating variable electric power comprising using a device of claim 12, wherein said device comprises a single cable comprising at least three electrical conductors inserted into an alloy referred to as having PTC behavior, this alloy itself being composed of polymers filled with electrically conductive particles.
